(19) United States
(12) Patent Application Publication
(10) Pub. No.: US 2026/0225819 A1
(43) Pub. Date: Aug. 6, 2026

(54) CONVEYOR ARRANGEMENT

(71) Applicant: INTERROLL HOLDING AG, Sant'Antonino (CH)

(72) Inventors: Siegmund Dudek, Hückelhoven (DE); Christian Hagmaier, Hückelhoven (DE); Michael Ströbel, Hückelhoven (DE)

(21) Appl. No.: 19/150,165

(22) PCT Filed: Jan. 26, 2024
(86) PCT No.: PCT/EP2024/051888

§ 371 Date: Jul. 22, 2025

(30) Foreign Application Priority Data
Jan. 27, 2023 (EP) 23153705.1

(51) Int. Cl. B65G 21/20; G06F 30/13

(52) U.S. Cl. CPC B65G 21/2072; G06F 30/13; B65G 2203/0233

(57) ABSTRACT

A conveyor arrangement, which includes: A) at least one or a plurality of conveyor zones, wherein each conveyor zone is adapted to convey an object from an inlet of said conveyor zone to an outlet of said conveyor zone along a conveying direction; B) a plurality of presence sensors adapted to detect the presence of an object to be conveyed within a predefined area of said conveyor zone; C) a side guide adapted to prevent an object from unintentionally leaving said conveyor zone laterally; in particular the side guide is adapted to divide a space around the conveyor in an inner area, in which said object is being conveyed, and an exterior area, where no object to be conveyed by the conveyor arrangement is located; wherein the side guide provides a closed guiding surface extending in vertical direction from the conveyor surface up to an upper edge.

### TECHNICAL FIELD

The invention refers to a conveyor arrangement.

### BACKGROUND OF THE INVENTION

EP 3 222 564 B1 discloses a conveyor for conveying an object from a start position to a target place. The conveyor comprises a plurality of zones into which the conveyor is divided, the object being conveyed across the zones; each of the zones comprising: a linear conveying zone that linearly conveys the object; a conveying direction changing zone selecting a conveying direction of the object to send out the object in the selected conveying direction; a conveyance destination storage unit that is configured to store the conveyance destination information temporarily; an information receiving unit that is configured to receive the conveyance destination information from an upstream zone; and an information transmitting unit that is configured to transmit the conveyance destination information to a downstream zone. The conveyor transfers the conveyance destination information from the upstream zone to the downstream zone with the movement of the object across the zones.

WO 2021/048042 A1 discloses a virtual layouter tool. Here a conveying arrangement can be created in the virtual world using 3D data of individual conveying modules. The 3D data of the conveying devices are arranged in a spatial relation to each other which conforms a possible relation of the relating real module devices in the real world. The created conveying arrangement in the virtual world can be used in a simulation mode for predicting an efficient use and configuring a sufficient capacity of the conveying arrangement.

US 2005/0087428 A1 discloses a conveyor for conveying articles along a conveying surface. The conveyor comprises a pair of opposite sidewalls, to which a number of motorized rollers are mounted (US 2005/0087428 A1, claim 1). The operation of the conveyor is performed in response to article sensors, positioned along the various zones of the conveyor (US 2005/0087428 A1, [0012]). As apparent from FIG. 14, the sensors are mounted directly to the opposite side walls of a support frame, to which the motorized rollers are mounted.

U.S. Pat. No. 5,582,286 A discloses a modular power roller conveyor having a conveyor section for transporting a product unit. The conveyor section comprises a left side rail 12 and a right side rail, wherein a plurality of carrier rollers 14 and drive rollers 16 mounted between said rails. An assembly of photosensors and respective sensor brackets is positioned in such a manner at the rails, that a beam from photosensor passes through said opening within the rail (col. 3, I. 46-55).

DE 10 2008 017 609 A1 discloses a system for conveying bottles or similar containers. The system comprises at least two adjoining and interconnected guide plates for forming a container guide. This container guide is designed in such a way that its upstream end, which the containers pass before entering a respective row, can be adjusted in the transport direction and against the transport direction (indicated by double arrow C in FIG. 1 of DE 10 2008 017 609 A). This is intended to achieve a staggered arrangement of the ends of the transport guide, wherein some container guides with upstream ends extending further into the area of the conveyor in front of a row divider than other container guides. This is intended to improve the stability of the transportation of the containers and to prevent the containers from falling over (DE 10 2008 017 609 A, [0016]).

### SUMMARY OF THE INVENTION

It is an object of of the disclosure to provide an improved conveyor device and in particular a method of planning/assembling the same. In particular the object is to provide a safe conveyor device, where the risk of injuries is reduced and at the same time the flexibility of positioning of presence sensors is given.

The conveyor arrangement includes,
at least one or a plurality of conveyor zones, each conveyor zone is adapted to convey an object from an inlet of said conveyor zone to an outlet of said conveyor zone along a conveying direction,
a plurality of presence sensors adapted to detect the presence of an object to be conveyed within a predefined area of said conveyor zone; the predefined area lies in particular within a field of view of the presence sensor;
a side guide adapted to prevent an object from unintentionally leaving said conveyor zone laterally.

In particular the side guide is adapted to divide a space around the conveyor in an inner area, in which said object is being conveyed, and an exterior area, where no object to be conveyed by the conveyor arrangement is located.

According to the invention the side guides provide a closed guiding surface extending in vertical direction from the conveyor surface up to an upper edge. In contrast to the conventional side guides (see in particular FIG. 1), the invention reduces any risk which may occur by a person putting his finger in the gaps between the side guides and other components such as the sensor including any fixing means for the sensor.

In an embodiment the side guide comprises a plurality of side guide sheets, wherein a first side guide sheet is located upstream of a second side guide sheet. Said first side guide sheet is located next to the second side guide sheet, in particular located gapless with the second side guide sheet, in particular in an overlapping manner, wherein overlapping refers here to the direction of travel. The advantage hereby is that also the transitional area between tow side sheets is free from any gaps, which may cause said injuries.

Unless stated otherwise, the terms upstream and downstream refer to the direction of travel.

In an embodiment, at least one of said side guide sheets comprises a sensor opening; wherein a presence sensor is aligned with the sensor opening, so that a field of view (V) of the presence sensor passes the sensor opening. In particular on the exterior side of the sheet the sensor may close the opening, improving the safety of the side guide.

In an embodiment the sensor opening is located at the bottom of the side guide sheet, in particular so that the field of view of the sensor is located short above the level of the conveyor surface, enabling that also very flat objects can be detected by the sensor.

The term sensor is to be understood broadly and may comprise more than just an active part of a sensor arrangement; in particular the term sensor also comprise any optical passive components, which are necessary for presence detection, such as a reflector. As a consequence, a reflector located behind a sensor opening may be understood as a sensor.

In an embodiment the first and the second side guide sheets are overlapping each other at an overlapping area in a direction parallel to the conveying direction. The overlapping condition prevents again any risk of injuries, thereby enabling a flexibility in the positioning of the side guide sheets. As explained below, the position of the side guide sheets may be limited by the position of the sensors, which reduces the freedom to position all side guide sheets.

Thereby the overlapping length of the overlapping area is in particular adjustable.

In an embodiment the first side guide sheet is located upstream to the second side guide sheet. In the overlapping area the first side guide sheet is located inwards in direction to the inner area, relative to the second side guide sheet. This arrangement is supporting a smooth transition of any objects sliding along the overlapping side guides.

In an embodiment the side guide sheet has
a first guiding surface, in particular wherein the sensor opening is located in said first guiding surface, and
a second and/or third guiding surface being located angled or offset parallel to the first guiding surface.

The first guiding surface is located downstream of the second and/or third guiding surface, wherein
the first guiding surface is located more inwards in direction to the inner area compared to the second and/or third guiding surface, and/or
the second guiding surface is arranged at an angle to the first guiding surface and, starting from the first surface, points away in the direction of the exterior area.

In an embodiment the presence sensor is held at a lateral distance from the side guide, in particular form the side guide bracket and/or the side guide opening. A sensor vision tube is provided bridging the lateral distance and enclosing a space around a field of view of the sensor. Said tube also increases the safety thereby allowing the sensor to be held at a distance. The tube therefore extends the “unsafe” interior area behind the level of the side guide and allows nevertheless an unobstructed view on to the objects.

In an embodiment there is no transparent covering on the sensor opening, which could be damaged or get polluted or otherwise may negatively affect the field of view of the presence sensor.

Since no other sensors are mentioned within the present application the terms sensor and presence sensor are used synonymously.

The claimed method of planning and/or assembling a conveyor arrangement as described above includes the following steps:
defining a position of at least one presence sensor at the conveyor zone; and
based on the defined position of the at least one presence sensor, planning and/or assembling the side guide.

Said method taking into account that the sensor position is defined based in the conditions set up by the conveyors itself. The predefined sensor position is then used to plan or (directly) assemble the side guide. Since the side guides comprise closed surfaces, the side guides need to respect the position(s) of the sensor(s).

In particular in the above method said position of said presence sensor is defined in a manner, that a sensor opening of the side guide) is aligned with one of said presence sensors, in particular in a manner that a field view of the sensor passes through the sensor opening.

In an embodiment planning and/or assembling the side guides includes the step of selecting a plurality of side guide sheets, where the side guide sheets include
first side guide sheets comprising a sensor opening.

In an embodiment in a second step of planning and/or assembling the side guides, the first side guide sheets are selected and positioned in alignment with the presence sensors, and in a subsequent second step of planning and/or assembling the side guide, the second side guide sheets are selected and positioned in a manner so as to close a gap between two first side guide sheets.

The invention enables, that in the second step of planning and/or assembling the side guides, the position of the second side guide sheets is defined in a stepless manner.

In an embodiment the conveyor arrangement is adapted to convey an object from at least one feed in station selectively to a selected destination from a plurality of destinations.

In an embodiment the conveyor arrangement comprises a plurality of conveyor zones. Said conveyor zones are arranged in a manner, that said object can be transferred from an outlet of a previous, in particular direct, upstream conveyor zone to an inlet of a subsequent downstream conveyor zone.

In an embodiment the conveyor arrangement comprises at least one or a plurality of controllers, adapted to control the operation of the conveyor zones. Said controller controls the operation of the conveyor zone based on a sensor signal provided by a presence sensor. The presence sensor is adapted to detect the presence of an object to be conveyed within the conveyor zone, in particular within a predefined area of the conveyor zone.

In particular the steps of selecting and positioning can be done virtually by means of a layouter tool or similar; selecting and positioning can alternatively be done with real hardware, where the real hardware is thereby actually assembled.

The material of the side guide, in particular the side guide sheet can be various; in particular the material is from metal or plastic.

### BRIEF DESCRIPTION OF THE DRAWINGS

An example embodiment of the invention is described in more detail with the help of the figures; herein show:

FIG. 1 a conventional conveyor zone in perspective view;

FIG. 2 a conventional basic conveyor arrangement;

FIG. 3. schematic representations of different conveyor zones;

FIG. 4 principal sketch of a conveying arrangement;

FIG. 5 a personal computer on which the layouter is running in an initial planning step;

FIG. 6 the personal computer of FIG. 5 in a subsequent planning step;

FIG. 7 the personal computer of FIG. 6 in a subsequent planning step;

FIG. 8 the personal computer of FIG. 7 in a subsequent planning step;

FIG. 9 the construction area within the layouter in a subsequent planning step;

FIG. 10 a perspective view on a section of an inventive conveyor arrangement;

FIG. 11 a) a more detailed perspective view on the conveyor arrangement according to FIG. 11;

b) a schematic top view on the conveyor arrangement according to FIG. 11;

FIG. 12 a catalogue of various side guide sheets; and

FIG. 13 detailed perspective views on the sensors of the conveyor arrangement according to FIG. 11.

### DETAILED DESCRIPTION

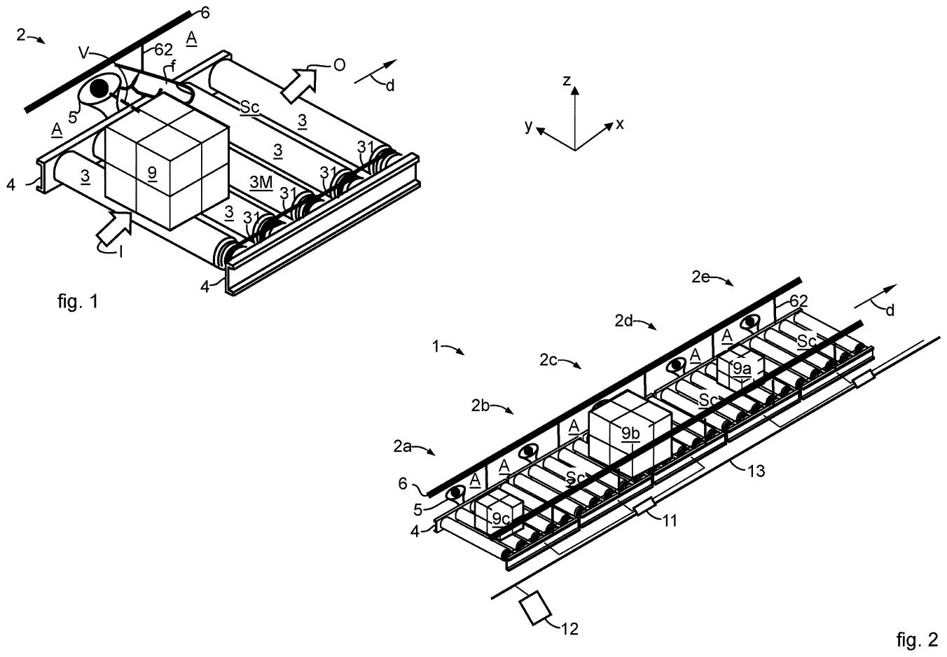

FIG. 1 shows an exemplary conveyor zone 2, having several conveyor rollers 3 which are driven together by a common motor. For this purpose, one of the conveyor rollers is designed as a motorized conveyor roller 3M. The motorized conveyor roller 3M is driven in particular by a three-phase motor arranged within the conveyor roller. Via one or more drive connectors 31, e.g. a drive belt, the conveyor rollers 3 of a conveyor zone 2 are drive-connected to each other and are jointly driven by the motorized conveyor roller 3M. An upper side of the rollers form a conveyor surface Sc, on which an object 9 is in particular linearly conveyed from an inlet I to an outlet O along a conveying direction d.

In another embodiment a conveyor belt is used instead of rollers; accordingly the conveying surface Sc is formed by an upper side of the conveyor belt (not shown in FIGS. 1 and 2).

By means of a presence sensor 5, the presence of a conveyed object 9 arranged on the conveyor zone 2 can be determined as soon as the object comes into the field of view V of the sensor. The presence sensor 5 does not necessarily cover the entire conveyor zone 2; it is sufficient if the presence of a conveyed object 9 within a partial area of the conveyor zone 2 is detected by the presence sensor 5. The presence sensor 5 thereby generates a sensor signal, which is connected via a signal line (not shown) to a local zone controller 11 (see FIG. 2) presented further below.

In particular the presence sensor 5 includes a photoelectric sensor, in particular in the form of a through-beam type or a reflective type (see https://en.wikipedia.org/wiki/Photoelectric_sensor, version of 16.11.2022), also often called “light barrier”. Any other sensor based on light detection may be used instead.

The conveyor rollers 3 and the presence sensor 5 are attached to a common support frame 4. The conveyor rollers 3 of several conveyor zones 2 can be attached to a common support frame 4.

The motorized conveyor rollers 3M are each controlled by at least one or a plurality of zone controllers 11. A local zone controller 11 can control the motorized conveyor rollers of several conveyor zones 2. A plurality of zone controllers 11 are arranged in a conveyor arrangement 1 (FIG. 2), which communicate with each other via a bus connection 13.

FIG. 2 shows a basic conveyor arrangement 1, where conveyor zones 2 a . . . e as described previously are used. A plurality of zone controllers 11 control the operation of the conveyor zones 2. A PLC 12 (programmable logic control) may be provided to control the overall operation of the conveyor arrangement 1.

Scanners (not shown) may be arranged along the zones and provide identification data relating to objects 9a . . . c passing the scanner in the zones. These identification data are sent via bus connection 13 to the PLC 12. The PLC 12 has access to an object data base (not shown), which provides destination data based in the identification of the objects 9. Based on the acquired data the PLC 12 provides operation instruction to a local zone controller 11, how to handle the object 9, i.e. to which of the outlets O said object 9 is to be conveyed.

In an alternative embodiment as described in European patent application 22 180 381.0, no PLC or similar is required. Instead of a PLC the zone controllers are connected to a common higher-level object data broker, in particular via the bus connection, with which the zone controllers are also connected to one another. The data broker provides destination data related to the identified objects and the zone controllers are adapted to control operation of the zones based on the provided destination data.

In particular the zone controllers 11 control the motorized conveyor rollers 3M in such a way that the successively approaching conveyed objects 9 do not collide with each other, which is usually called “zero pressure accumulation”. The control takes place in such a way that essentially only one conveyed object 9 is present per conveyor zone 2. However, slight overlaps may occur. For example, an upstream conveyed object 9b located on an upstream conveyor zone 2c may already enter a downstream conveyor zone 2d even though the downstream conveyed object 9a has not yet left this downstream conveyor zone 2d completely. Among other things, the sensor signals of the presence sensors 5 serve as input variables here, although it is ensured that the two conveyed objects 9 do not touch and thus do not damage each other.

The conveyor zones 2 are equipped with a lateral side guide 6, adapted to laterally support the objects 9, preventing that the object laterally fall off the conveyor zone 2. Conventionally the side guide 6 is in the form of a guide rail, which is supported by a number of support rods 62, mounted at the frame 4 (FIGS. 1 and 2). Between the frame 4, the side guide 6 and the rods 62 an opening A is created between two rods 62 through which a finger f (see FIG. 1) can be inserted. When the finger f is inserted through the opening A, a passing object 9 can cause an injury to the finger f due to heavy shearing forces.

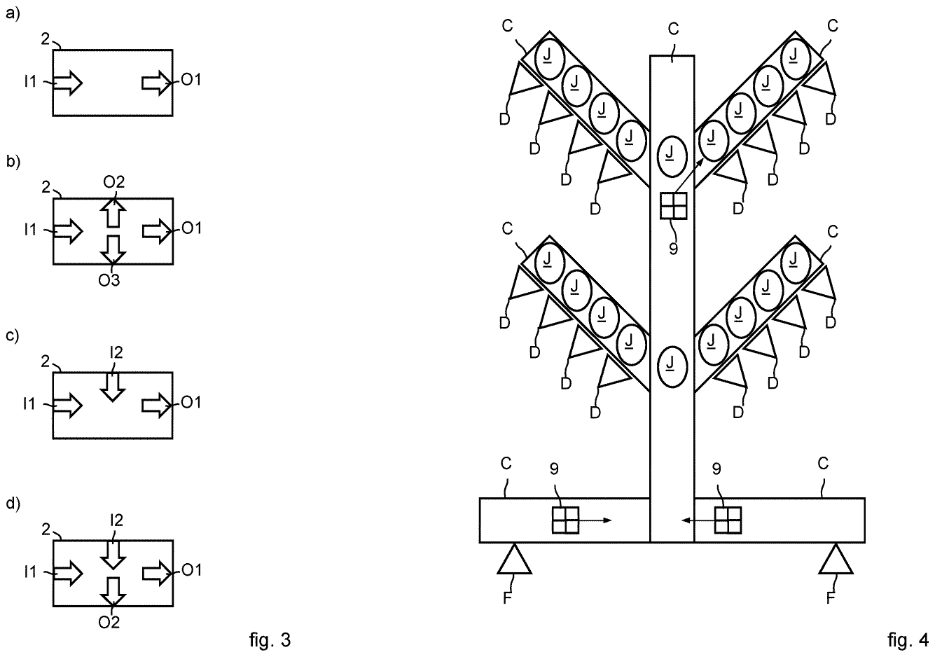

In the following course of the invention, reference is made to conveyor zones 2, using a schematic representation of said conveyor zone 2 as shown in FIG. 3. Here FIG. 3a represents schematically a conveyor zone 2 of FIG. 1, which has one first inlet 11 and one first outlet O1. No more inlets and outlets are provided. The conveyor zone 2 can also be curved or from other shape.

FIG. 3b shows the representation of another conveyor zone 2 having an extended scope of operation. Here in addition to the conveyor zone 2 of FIG. 3a the conveyor zone 2 has an additional, second outlet O2. The object 9 can be conveyed selectively from said first inlet 11 to one of said first and second outlets O1, O2. Optionally, the conveyor zone 2 has an additional, third outlet O3. In this option, the object 9 can be conveyed selectively from said first inlet 11 to one of said first, second and third outlets O1, O2, O3.

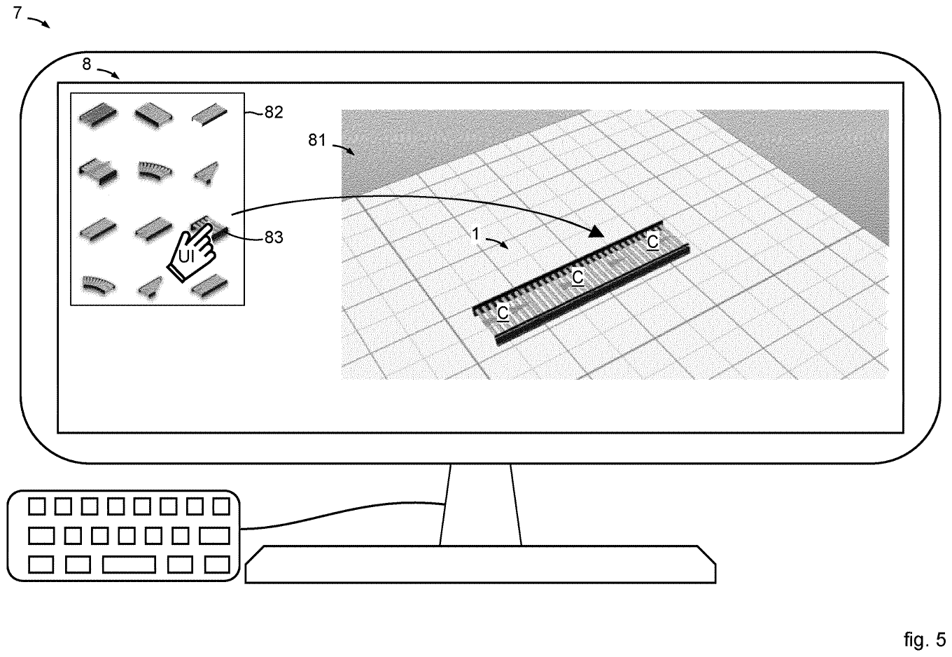

As an example, said conveyor zone 2 of FIG. 3b can be formed by a conveyor zone 2 as shown in FIG. 1, which additionally is provided with a transfer device as described with reference to FIG. 5 of EP 3 222 564 B1 (in this document and figure the transfer device has reference sign 20).

FIG. 3c shows the representation of a conveyor zone 2 having an extended scope of operation. Here in addition to the conveyor zone 2 of FIG. 3a, the conveyor zone 2 has an additional second inlet 12. Objects 9 can be conveyed from one of said first and second inlets 11, 12 to said first outlet O1.

The transfer device as described with reference to FIG. 3b may also be suitable to provide said additional second inlet 12.

FIG. 3d shows the representation of a conveyor zone 2 having an extended scope of operation. Here in addition to the conveyor zone 2 of FIG. 1 the conveyor zone 2 has an additional second inlet 12 and an additional second outlet O2 and is an example as a combination of the embodiments of FIGS. 3b and 3c.

All conveyor zones 2 are controlled by a zone controller 11 as shown in FIG. 1 or 2, in particular wherein one zone controller 11 may be adapted to control the operation of more than one zone 2.

Starting from FIG. 4 the planning of a conveying arrangement 1, which is performed by a person, herein called the planner.

FIG. 4 shows a principal sketch of what the conveying arrangement 1 should finally look like.

The conveyor arrangement 1 according to the sketch has two feed in stations F, where a user can input objects 9 to be conveyed. From the feed in stations F the objects 9 are conveyed to several destinations D by several conveyors C. A plurality of junctions J are provided, at which the objects 9 are selectively transferred onto one of a plurality of routes along the conveyors C. Such a sketch may be only available in the head of a planner.

Reference is now made to FIG. 5. For detailed planning the planner uses an IT tool 8, which is an application program running on a personal computer 7, where the term personal computer also includes tablet PC or similar devices. The IT tool 8 is herein also called the “layouter”.

The layouter 8 provides a construction area 81 in which the planner can create a digital representation of a conveying arrangement 1. The layouter 8 provides a selection area 82, in which components are provided for being selected by the planner. By a user interaction UI the user can select a graphical representation 83 of a certain component and transfer the selected component via drag & drop into the construction area 81.

After a few repetitions a small conveying arrangement 1 has been created already in the construction area 81, comprising a straight line of roller conveyors C.

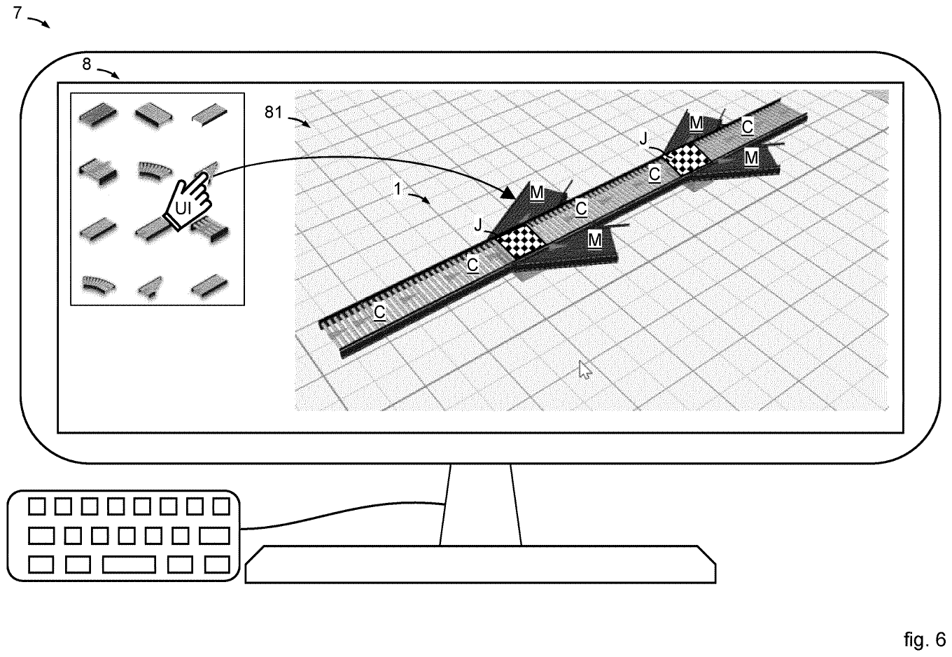

FIG. 6 shows in the construction area 81 the representation of the further developed conveyor arrangement 1. In addition to the situation in FIG. 5, the conveyor arrangement 1 comprises now the junctions J as well as a number of merges M branching off at the junctions J.

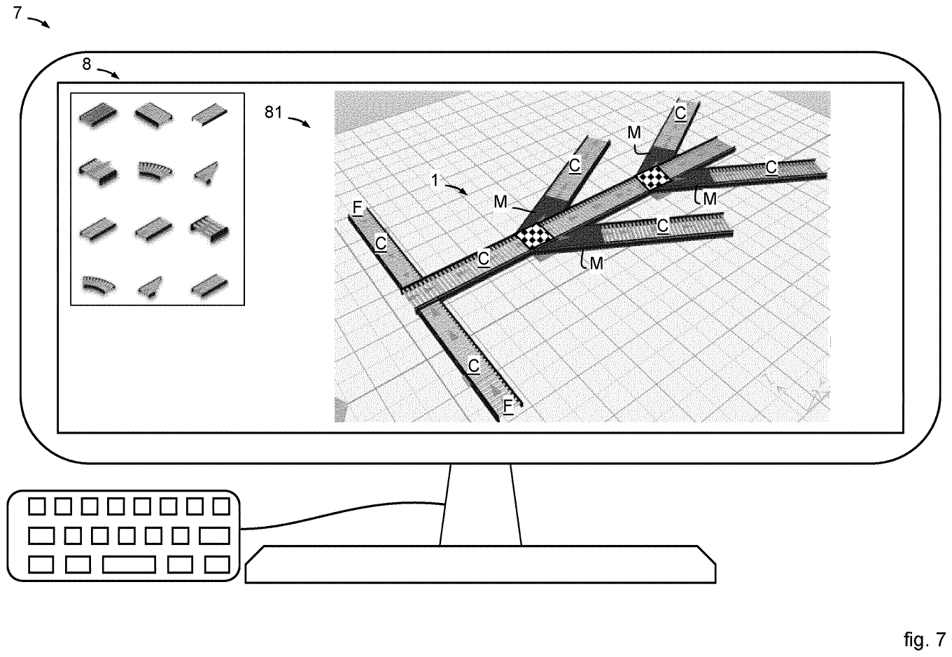

FIG. 7 shows in the construction area 81 the representation of the further developed conveyor arrangement 1. In addition to the situation in FIG. 6, the conveyor arrangement 1 comprises now additional conveyors C downstream of the merges M. Also the feed in stations F and the connecting conveyors C are provided, which are connected via a junction J to the previous conveyors C.

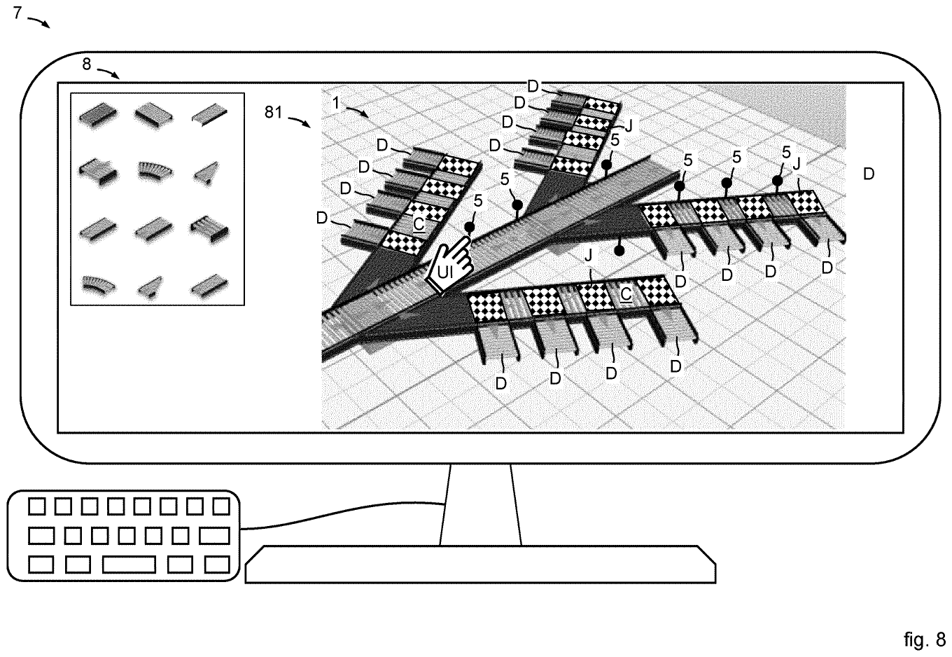

FIG. 8 shows in the construction area 81 the representation of the further developed conveyor arrangement 1. In addition to the situation in FIG. 7, the conveyor arrangement 1 comprises the destinations D branching off from the conveyors C downstream of the merges M. Additional junctions J are provided where the destinations D branching off from conveyors C.

As can be realized by a comparison between the FIGS. 8 and 7 the focus of the construction area can be varied by the planner.

The junction J can be realized by various embodiments. As a usual embodiment a junction J can be established by a roller conveyor which is equipped with a transfer device such as shown e.g. in FIG. 5 of EP 3 222 564 B1.

Also a plurality of presence sensors 5 are included in the representation of the conveyor arrangement 1. The presence sensors 5 are positioned by a user input UI at a position, where it is required for proper controlling the conveyor arrangement 1.

Now representations of the main components, which during intended usage perform the conveying and sorting operations, are provided in the conveyor arrangement 1 within the construction area 81 according to FIG. 8.

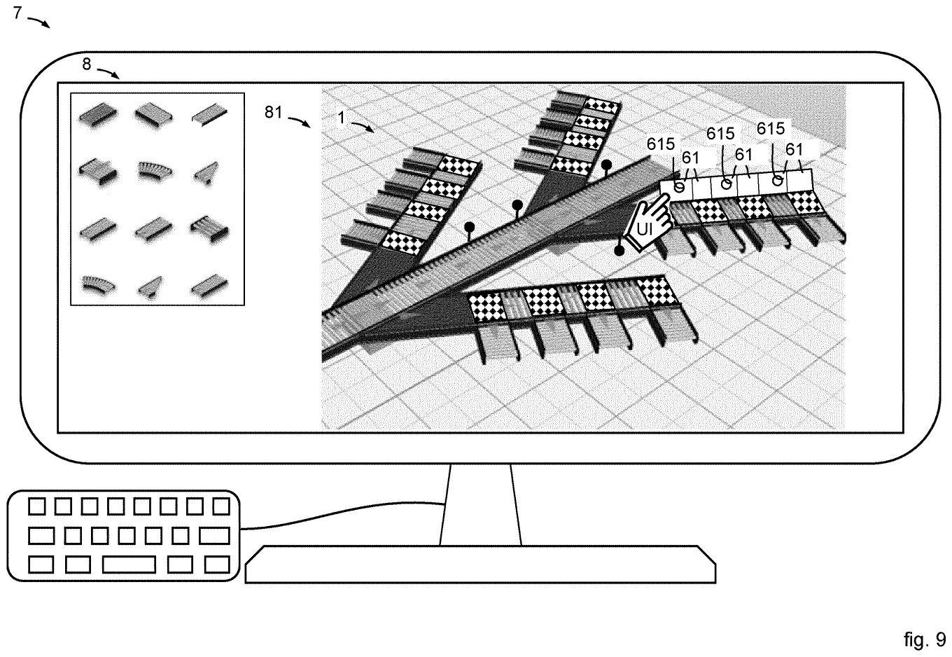

According to FIG. 9 the user can insert a side guide 6 to the existing representations. The side guide 6 has a plurality of side guide sheets 61 providing a closed guiding surface to enable the sensors 5 to detect the presence of an object 9 on the conveyor surface. Some side guide sheets 61 comprise a sensor opening 615, enabling the sensor 5 to look through the side guide sheet 61.

As apparent the side guide is made separate to the frame of the conveyor.

During planning the conveyor, the side guide sheets 61 are therefore selected and positioned based on the position of the sensor 5; said position is therefore defined prior to selection and positioning the side guide sheets 61.

The It planning tool provides for this task support. In case that the defined side guide 6 does not match to the position of the sensor 5, the IT planning tool may provide an alert indicating said mismatch to the user. Here the alert may have different embodiments. As an example a pop up window may appear, indicating said mismatch; an alternative alert is that the IT planning tool simply provides feedback in a manner, that the user is not allowed to position a side guide in a mismatching position.

Alternatively or in addition the IT planning tool can automatically define the side guide based on the position of said sensor. As an example the IT planning tool may select a guide sheet 61 having a sensor 610 (instead of a sensor having no sensor opening) and positions the selected side guide sheet automatically in a manner that the sensor opening 610 is in alignment with the sensor 5.

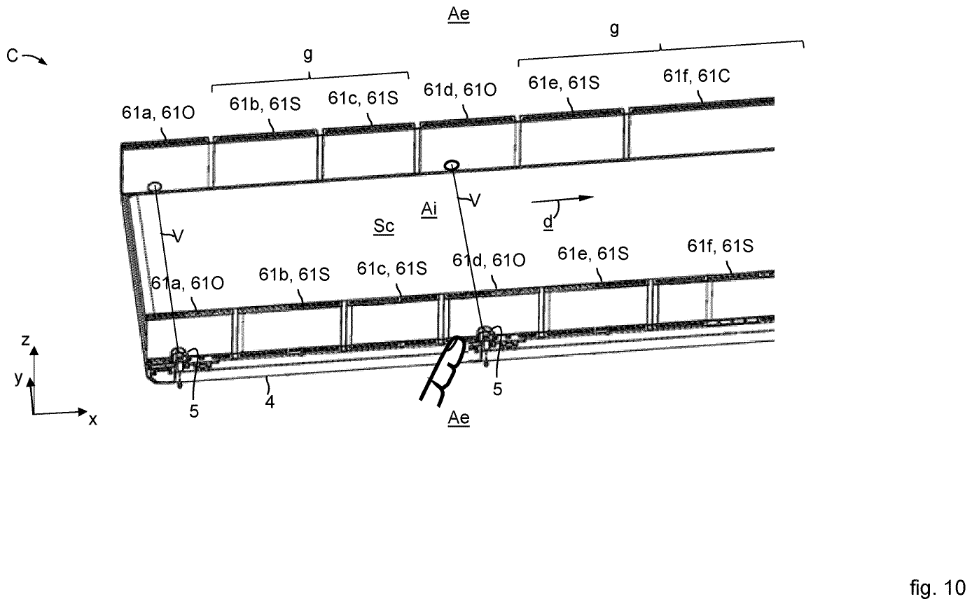

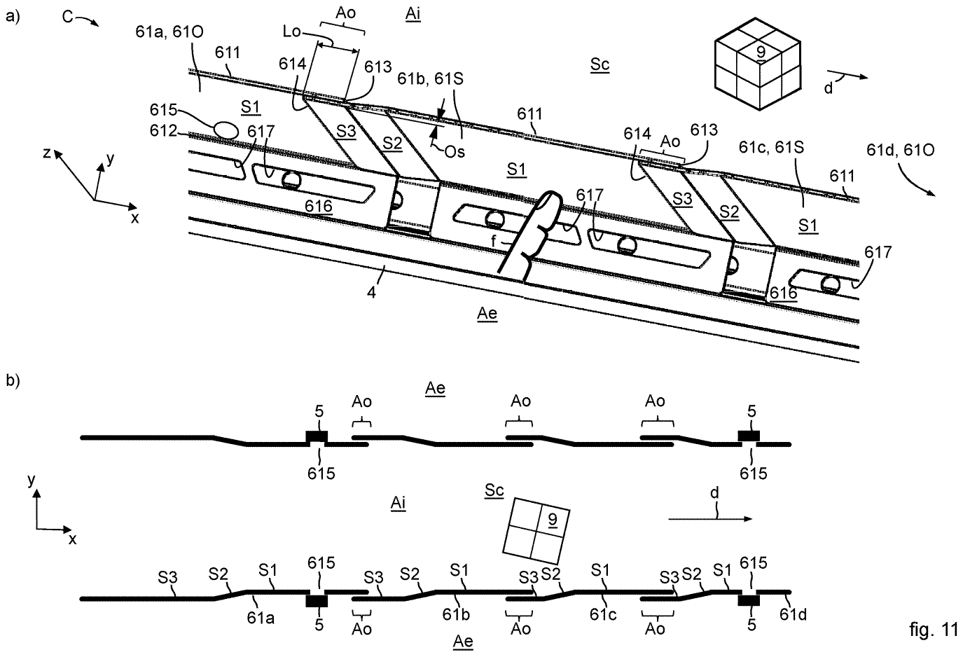

FIG. 10 shows a section of an exemplary conveyor C in perspective view. Here the conveyor surface Sc is formed by the upper side of a conveyor belt (but it is also possible that the conveyor surface Sc is formed by the upper side of a number of rollers). Details of the side guide sheets 61 are shown in FIG. 11.

The side guide sheets 61 forming a closed guiding surface extending from a bottom edge 612 to a top edge 611 and from a front edge 613 to a rear edge 614. With respect to the conveying direction d the front edge 613 is hereby located downstream and the rear edge 614 is located upstream. The side guide sheets are separate to the frame 4.

The closed guiding surface divides the room in an interior area Ai and an exterior area Ae. In the inner area is an area where objects 9 travel at high speed causing in general a certain risk of injuries. In contrast thereto the exterior area Ae is a safe area for the finger f of a person.

The closed guide surface prevent, in contrast to the situation of FIG. 1, that a person can protrude a finger anywhere between the fixed component from the exterior area Ae into the interior area Ai.

The side guide sheets 61 have a fixing section 616, where the side guide sheets 61 are fixed to the frame 4 of the conveyor C. In particular the fixing section 616 comprises at least one or more elongated fixing holes 617.

For better illustration the individual side guide sheets 61 are provided with reference signs 61a, 61b, 61c, 61d, where the suffix a, b, c, . . . indicates the position of the individual side guide sheets 61 in the conveying direction d. Consequently an individual second side guide sheet 61b is located downstream of an individual first side guide sheet 61a, etc.

The side guide sheets 61 are additionally provided with another reference sign, which indicates the type of side guide sheet. A first type of side guide sheet 61O is provided with said sensor opening 615 within the closed guiding surface. A second type of side guide sheet 61S is not provided with said opening and is therefore completely closed.

As already indicated above, in a first step the positions of the sensors 5 are defined. After the positions of the sensors 5 are defined, side guide sheets 61O of the first type are selected in a second step and positioned in a manner, that the sensor opening 615 is in alignment with the position of the sensor 5. So in the conveyor according to the FIG. 1, the first side guide sheet 61a and the forth side guide sheet 61d are positioned along the conveying direction d.

After the second step a gap g remains between the first side guide sheet 61a and the fourth side guide sheet 61d. In the same manner there are pluralities of gaps g, e.g. a gap between the fourth side guide sheet 61d and the next side guide sheet of the first type 61O (not shown in FIG. 11).

In a third step at least one or a plurality of side guide sheet 61b, 61c, 61e, 61f, . . . of the second type 61S are selected and positioned in the gaps. The selection is performed in a manner, so that a continuous side guide surface is established which extends over the plurality of side guide sheets without any gaps remaining between the individual adjacent side guide sheets.

To fulfill the selection and positioning with the aforementioned requirement, a set of side guide sheets 61 of different sizes are provided. E.g. the first side guide sheet 61a is of a smaller size and the sixth side guide sheet 61f is of a larger size. The remaining side guide sheets 61b, 61c, 61d, 61e are of different intermediate sizes.

Additionally the side guide sheets 61 are adapted to be positioned in a stacked manner to each other (FIG. 11). Therefore, in an overlapping area Ao, adjacent side guide sheets 61 are overlapping each other in a direction parallel to the conveying direction d at an adjustable overlapping length Lo.

The side guide sheets 61 are located next to each other without leaving a gap g between each other. The overlapping condition enables, that with limited number of different sized side guide sheets 61 every configuration can be achieved even under the condition, that the sensor 5 can be freely positioned without any limitation issued by the availability of suitable side guide sheets 61.

The first side guide sheet 61a is located upstream to the second side guide sheet 61b. In the overlapping area Ao the upstream first side guide sheet 61a is located inwards in direction to the inner area Ai, relative to the downstream second side guide sheet 61b. By this arrangement it is enabled, that the object 9 can smoothly pass the transition between the side guide sheets 61 in conveying direction d, without detrimentally abutting an any rear or front edge 613, 614 of the side guide sheets 61.

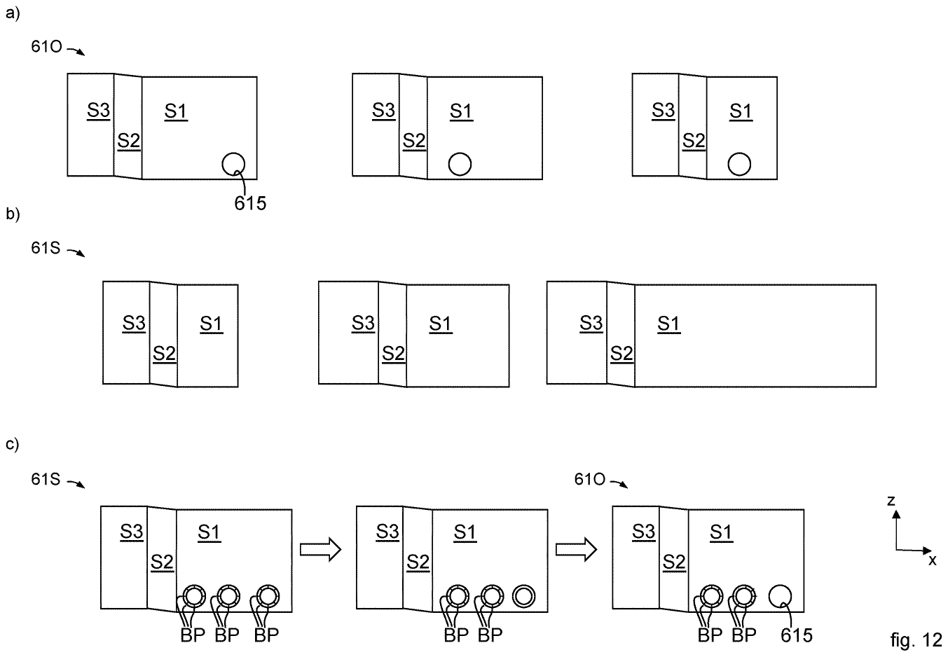

FIG. 12 shows a plurality of side guide sheets 61 which are selectable from a catalogue of a plurality of different predefined side guide sheets 61, which are available in a prefabricated way. The catalogue comprises two types of side guide sheets 61. The side guide sheets 61O of a first type (FIG. 12a) have a sensor opening 615; the side guide sheets 61S of a second type (FIG. 12b) do not have a sensor opening 615.

FIG. 12c shows an optional improvement. Here a side guide sheet 61S of the second type has, in particular in a first guiding surface S1, circular lines of predetermined breaking points BP, in particular generated by laser cutting. The predetermined breaking points BP can be broken, e.g. with the help of a cutting tool. After the predetermined breaking points BP are broken, a sensor opening 615 is generated, so that the side guide sheet 61O of the first type can be generated on demand from a side guide sheet 61S of the second type. This can be done on demand and on site at the final location, where the conveyor is assembled.

FIG. 12 shows three guiding surfaces S1, S2, S3. A first guiding surface S1 forms the main guiding surface of the side guide sheet 61. A third surface S3 is located upstream of the first guiding surface S1. The third guiding surface S3 is intended to be in the above mentioned overlapping arrangement with a first surface S1 area of an upstream side guide sheet 61. An example of which is shown in FIG. 11. Here the third guiding surface S3 of a second (downstream) side guide sheet 61b is in partial overlapping condition with the first guiding surface S1 of first (upstream) side guide sheet 61a.

The first and third surface S1, S3 are oriented parallel to each other at an offset Os in direction perpendicular to the conveying direction d. The offset Os corresponds to a, in particular sheet metal, thickness of the side guide sheets 61. By varying the overlapping length Lo the side guide sheets can be aligned to each other in a stepless manner, so to enable the sensor openings 615 always to be in alignment with the sensors 5.

A second guiding surface S2 is located between the first and the third guiding surface S1, S3 and is angled to the first and third guiding surfaces at an obtuse angle, forming a transition between the first and the third guiding surfaces.

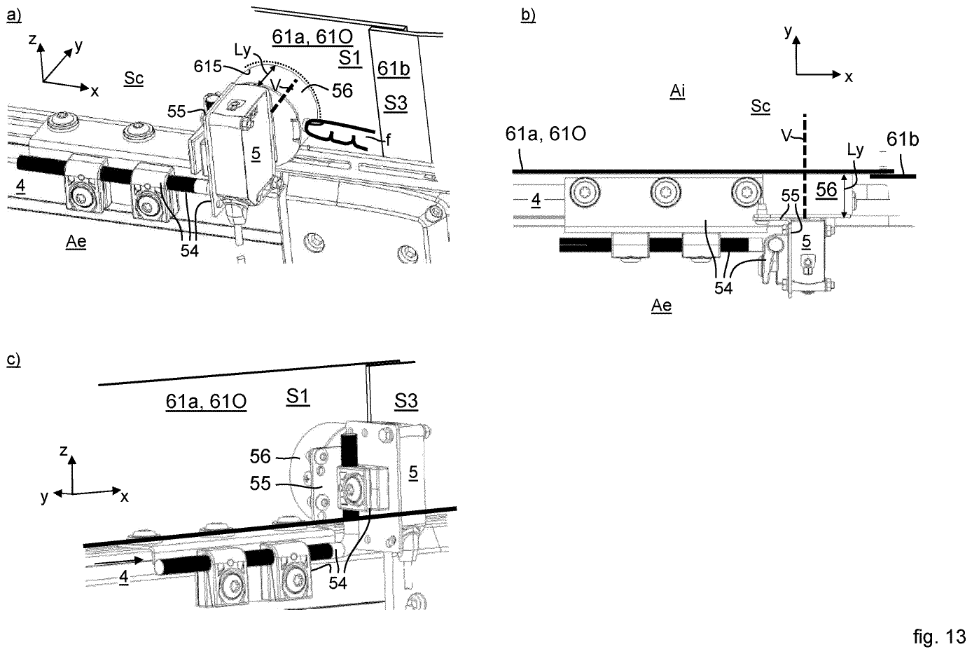

As shown in FIG. 13 the sensor 5 is mounted to the frame 4. Thereby a sensor fixing 54 is attached to the frame 4. A sensor mounting bracket 55 is attached to the sensor fixing 54. The sensor 5 is attached to the mounting bracket 55.

The presence sensor 5 is located at a lateral distance Ly from the side guide 6, the side guide sheet 61 and the sensor opening 615. In particular the remote location safes the sensor 5 from being damaged by any objects and obstacles in the inner area Ai. The lateral distance Ly between the sensor 5 and the side guide 6 is closed by a sensor vision tube 56. The sensor vision tube 56 encloses a space, in which a field of view V of the sensor 5 bridges the distance between the sensor 5 and the side guide 6, the side guide sheet 61 and/or the sensor opening 615. In particular obstacles can protrude from the exterior area Ae into the field view V of the sensor 5. Additionally the sensor vision tube 56 closes a gap between the sensor 5 and the side guide 6. It is therefore prevented that a person may protrude a finger f in this gap, which may otherwise cause a risk of injury as explained already in FIG. 1.

The side guide sheets 61 divide the area of the conveyor in an inner area Ai, where the goods are conveyed, and an outer area Ae. The inner area Ai is in particular a non-safe area, where injuries can occur here if a person reaches in during operation. Also the inner area Ai should be free from any edges and obstacles, which could prevent smooth conveyance of the objects 9.

### LIST OF REFERENCE SIGNS

1 conveyor arrangement
2 conveyor zone
2a . . . e
3 conveyor roller
3M motor-driven conveyor roller
31 drive connector
4 support frame
5 presence sensor
54 sensor fixing
55 sensor mounting bracket
56 sensor vision tube
6 side guide
61 side guide sheet
611 top edge
612 bottom edge
613 front edge
614 rear edge
615 sensor opening
616 fixing section
617 elongated fixing holes
62 support rod
7 PC, personal computer
8 IT tool/layouter
9 object to be conveyed
11 local zone controller
12 PLC
13 bus connection
81 construction area
82 selection area
83 graphical representation of a component
C conveyor
D destination
F feed in station
I inlet
I1 . . . 2
J junction
L line
M merge
O outlet
UI user interaction
f finger
Ao overlapping area
Ai interior area
Ae exterior area
d conveying direction
g gap
Lo length of overlapping area
Ly lateral distance
Os offset perpendicular to conveying direction
V field of view
Sc conveyor surface
S1,S2, S3 guiding surface
A opening
Oa overlapping area
610 first type side guide sheet
61S second type side guide sheet
SG1 . . . 3 side guide surface; guiding surface

1. A conveyer arrangement (1), comprising:
at least one or a plurality of conveyor zones (2), each conveyor zone (2) is adapted to convey an object (9) from an inlet (I) of said conveyor zone (2) to an outlet (O) of said conveyor zone (2) along a conveying direction (d),
at least one or a plurality of presence sensors (5) adapted to detect the presence of an object (9) to be conveyed within a predefined area of said conveyor zone (2); and
a side guide (6) adapted to prevent an object (9) from unintentionally leaving said conveyor zone (2) laterally;
in particular the side guide (6) is adapted to divide a space around the conveyor in an inner area (Ai), in which said object (9) is conveyed, and an exterior area (Ae), where no object to be conveyed by the conveyor arrangement is located;
characterized in that the side guide (6) provides a closed guiding surface (S1, S2, S3) extending in vertical direction (z) from the conveyor surface (Sc) up to a top edge (611).

2. The conveyor arrangement (1) according to claim 1, characterized in that the side guide (6) comprises a plurality of side guide sheets (61), wherein a first side guide sheet (61a) is located upstream of a second side guide sheet (61b), wherein the first side guide sheet (61a) is attached directly to the second side guide sheet (61b), in particular gapless with the second side guide sheet (61b), in particular in an overlapping manner.

3. The conveyor arrangement (1) according to claim 1, characterized in that at least one of said side guide sheets (61) comprises a sensor opening (615); wherein a presence sensor (5) is aligned with the sensor opening (615), so that a field of view (V) of the presence sensor (5) passes the sensor opening (615).

4. The convey arrangement (1) according to claim 1, characterized in that the presence sensor opening (615) is located at a bottom of the side guide sheet (61).

5. The conveyor arrangement (1) according to claim 1, characterized in that adjacent side guide sheets (61), in particular a first side guide sheet (61a) and a second side guide sheet (61b), are overlapping each other at an overlapping Area (Ao) in a direction parallel to the conveying direction (d).

6. The conveyor arrangement (1) according to claim 1, characterized in that the overlapping length (Lo) of the overlapping area (Ao) is adjustable.

7. The conveyor arrangement (1) according to claim 1, characterized in that a first side guide sheet (61a) is located upstream to a second side guide sheet (61b), wherein in the overlapping area (Ao) of the first side guide sheet (61a) is located inwards in direction to the inner area (Ai), relative to the second side guide sheet (61b).

8. The converyor arrangement (1) according to claim 2, characterized in that the side guide sheets (61) comprises:
a first guiding surface (S1), in particular wherein the sensor opening (615) is located in said first guiding surface (S1), and
a second and/or third guiding surface (S2,S3) being located angled or offset parallel to the first guiding surface (S1), wherein the first guiding surface S1 is located downstream of the second and/or third guiding surface (S2,S3), further wherein;
the first guiding surface (S1) located more inwards in direction to the inner area (Ai) compared to the second and/or third guiding surface (S2, S3), and/or
the second guiding surface (S2) is arranged at an angle to the first guiding surface (S1) and, starting from the first surface (S1), points away in the direction of the exterior area (Ae).

9. The conveyor arrangement (1) according to claim 1, characterized in that the presence sensor (5) is held at a lateral distance (Ly) from the side guide (6), in particular form the side guide bracket (61) and/or the sensor opening (615), and that a sensor vision tube (56) is provided bridging the lateral distance (Ly) and enclosing a space around a field of view (V) of the sensor (5).

10. The conveyor arrangement (1) according to claim 1, characterized in that the conveyor roller comprises a frame (4),
wherein at least one roller is attached to the frame (4),
wherein the side guide (6), in particular the side guide sheet (61) of the side guide (6), is made separate to the frame (4),
in particular wherein the roller is one of a motorized conveyor roller, an idler conveyor roller, a drum motor for driving a conveyor belt or a deflection roller for deflecting a conveyor belt.

11. A method of planning and/or assembling a conveyor arrangement (1) according to a claim 1, the method comprising the steps of:
defining a position of at least one presence sensor (5) at the conveyor zone (2); and
planning and/or assembling the side quide (6) based on the defined position of the at least one presence sensor (5).

12. The method according to claim 11, wherein the side guide (6) is defined in a manner, that a sensor opening (615) of the side guide (6) is aligned with one of said presence sensors (5).

13. The method according to claim 12, wherein the position of a side guide (6), in particular a side guide sheet (61), having said sensor opening (615) is defined after the position of said at least one presence sensor (5) has been defined.

14. The method according to any of claim 11, wherein defining, in particular planning and/or assembling, the side guide (61) comprises the step of selecting a plurality of side guide sheets (61), wherein the side guide sheets (61) comprise:
first type side guide sheets (61O) comprising a sensor opening (615), and
second type side guide sheets (61S) not comprising a sensor opening.

15. The method according to claim 14, wherein in a second step of planning and/or assembling the side guide (6), the first type side guide sheets (61O) are selected and positioned in alignment with the presence sensors (5), and in a subsequent second step of planning and/or assembling the side guide (6), the second type side guide sheets (61S) are selected and positioned in a manner so as to close a gap (g) between two first type side guide sheets (61O).

16. The method according to claim 14, wherein in the step of planning and/or assembling the side guide (6), the position of the second type side guide sheet (61S) is defined in a stepless manner.

17. The method according to claim 11, wherein in case the method refers to the planning of the conveyor arrangement, the method is performed by employing an IT planning tool (8), wherein the IT planning tool (8) provides a user interface (8) through which the user can provide a user interaction (UI) for defining, in particular selecting and/or positioning, the side guides and/or the sensor positions and/or the positions of the side guide sheets.

18. The method according to claim 17, wherein the IT planning tool (8) is adapted;
to automatically compare a defined position of a presence sensor (5) with a definition of a side guide and based on the comparison the IT planning tool is adapted to provide an error message for the case that said definition of a side guide does not match to said defined position of a presence sensor (5), and/or
to automatically define a side guide or adjust a definition of a side guide in a manner so that it matches to the position of the presence sensor.

19. The method according to claim 18, wherein the definition of said side guide matches with the position of the presence sensor in case that a sensor opening of said side guide is aligned with the position of the presence sensor, wherein the definition of said side guide does not match with the position of the presence sensor in case that no sensor opening of said side guide is aligned with the position of the presence sensor.
